(19) United States
(12) Patent Application Publication
(10) Pub. No.: US 2012/0299156 A1
(43) Pub. Date: Nov. 29, 2012

(54) WAFER PROCESSING METHOD

(75) Inventor: Po-Ying Chen, Kaohsiung City (TW)

(73) Assignee: PO-Ying Chen, Kaohsiung City (TW)

(21) Appl. No.: 13/117,310

(22) Filed: May 27, 2011

(51) Int. Cl. H01L 21/20; H01L 29/12

(52) U.S. Cl. 257/616; 438/492; 257/E21.09; 257/E29.068

(57) ABSTRACT

A wafer processing method includes the steps of: (a) annealing a silicon wafer at a temperature higher than 650° C.; (b) after step (a), depositing a silicon-germanium layer on the silicon wafer; (c) after step (b), implanting oxygen ions into the silicon wafer; and (d) after step (c), annealing the silicon wafer at a temperature higher than 650° C. to form a silicon oxide layer underneath the silicon-germanium layer.

### BACKGROUND OF THE INVENTION

1. Field of the Invention

This invention relates to a wafer processing method, more particularly to a wafer processing method that is used to process a low quality test wafer.

2. Description of the Related Art

Silicon wafers are usually produced by slicing a silicon single crystal ingot that is formed by Czochralski method. The sliced silicon wafers are classified into high quality wafers and low quality wafers according to the amount of defects thereof. The high quality wafers, so-called epi-wafer or prime wafer, are located in the middle part of the silicon single crystal ingot. The low quality wafers are sliced from end parts of the silicon single crystal ingot, are usually used as test samples in the laboratory because of high defects thereof, and thus are commonly known as test wafer, dummy wafer or monitor wafer. Since the test wafers cannot be used in the industry, the selling price thereof is about 10 to 20% of that of the prime wafers.

To remove the defects mentioned above, TW patent no. I263329 discloses a method for manufacturing a SIMOX (Separation by Implanted Oxygen) wafer. In this method, a cleaning process is carried out before an annealing step in order to remove particles that adhere to a silicon wafer upon doping oxygen ions in the silicon wafer, thereby preventing formation of defects in the subsequent annealing step. However, the SIMOX wafer produced by the method still has problems of non-uniform thickness of a buried silicon oxide layer formed in the silicon wafer after the annealing step, and inferior smoothness of the surface of the SIMOX wafer.

### SUMMARY OF THE INVENTION

The object of the present invention is to provide a wafer processing method that can produce a high quality wafer.

The wafer processing method according to the present invention comprises the steps of: (a) annealing a silicon wafer at a temperature higher than 650° C.; (b) after step (a), depositing a silicon-germanium layer on the silicon wafer; (c) after step (b), implanting oxygen ions into the silicon wafer; and (d) after step (c), annealing the silicon wafer at a temperature higher than 650° C. to form a silicon oxide layer underneath the silicon-germanium layer.

### BRIEF DESCRIPTION OF THE DRAWINGS

The above and other features and advantages of the present invention will become apparent in the following detailed description of the preferred embodiments with reference to the accompanying drawings, of which:

FIG. 1 illustrates consecutive steps of the first preferred embodiment of a wafer processing method of this invention;

FIG. 2 is a schematic view showing the silicon wafer produced by the method shown in FIG. 1;

FIG. 3 is a scanning electron microscopic photograph (magnification ×6000) showing the sectional view of the silicon wafer shown in FIG. 2;

FIG. 4 illustrates consecutive steps of the second preferred embodiment of a wafer processing method of this invention; and

FIG. 5 is a schematic view showing the silicon wafer produced by the method shown in FIG. 4.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

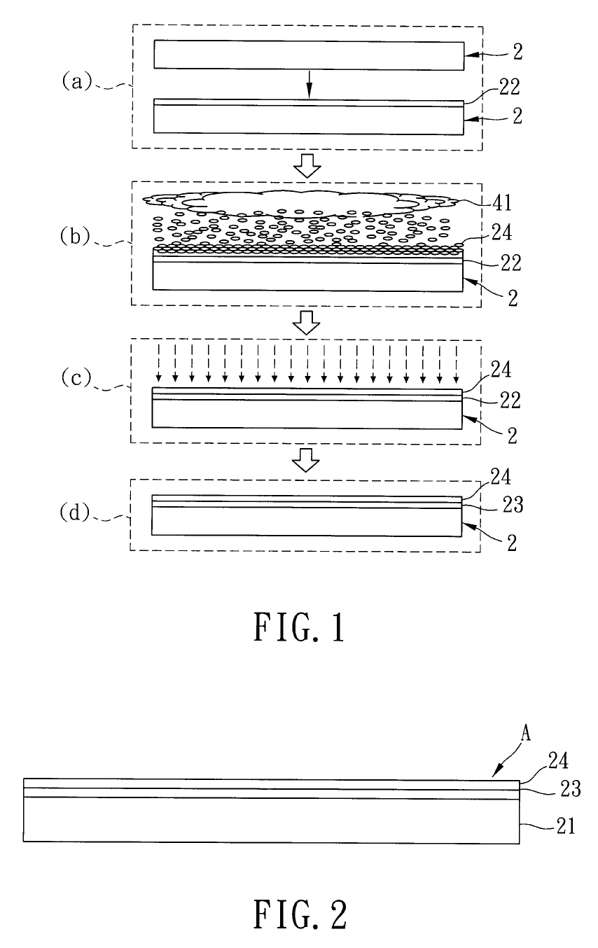

FIG. 1 shows the first preferred embodiment of a wafer processing method according to the present invention. The wafer processing method comprises the steps of: (a) annealing a silicon wafer 2 at a temperature higher than 650° C. so as to form a denuded zone layer 22, i.e., a high quality silicon layer; (b) after step (a), depositing a silicon-germanium layer 24 on the denuded zone layer 22 of the silicon wafer 2; (c) after step (b), implanting oxygen ions into the silicon wafer 2; and (d) after step (c), annealing the silicon wafer 2 at a temperature higher than 650° C. to form a silicon oxide layer 23 underneath the silicon-germanium layer 24.

It is worth mentioning that the silicon wafer 2 used in the wafer processing method of this invention is referred as a low quality and high crystalline defect silicon wafer, which is sliced from the ends part of a silicon single crystal ingot. Alternatively, the silicon wafer 2 used herein can be the one that fails to meet quality control inspection.

In this embodiment, step (a) is conducted in a furnace tube under an atmosphere that is selected from the group consisting of hydrogen, argon, nitrogen and rare gas for 10 minutes to 60 minutes, thereby producing the denuded zone layer 22 that is substantially free from crystalline defects and that has a smooth surface. To be specific, after the silicon wafer is subjected to an annealing treatment at high temperature, the silicon that is near a surface of the silicon wafer and that has high crystalline defect will be reconstituted due to a denuded zone effect so as to obtain the denuded zone layer 22 with high quality.

Step (b) is performed through a chemical vapor deposition method using a gas source 41 containing germanium and silicon. It should be noted that other deposition methods can be applied in this invention. Since the denuded zone layer 22 has a smooth surface, the germanium-silicon layer 24 deposited thereon could have perfect crystalline structure and a smooth surface, and thus, the processed silicon wafer A obtained through the method of this invention has a relatively smooth surface.

In step (c), the oxygen ions are implanted into the silicon wafer 2 using an ion implantation apparatus (not shown) at a concentration ranging from 1×10¹³ atmos/cm³ to 5×10²¹ atmos/cm³, and a depth ranging from 0.001 μm to 5 μm.

Next, step (d) is conducted in a furnace tube under an atmosphere selected from the group consisting of hydrogen, argon, nitrogen and rare gas for 10 minutes to 4 hours to form the silicon oxide layer 23, thereby obtaining a processed silicon wafer A (see FIG. 2). Alternatively, the annealing in steps (a) and (d) may be conducted in a rapid thermal process apparatus.

Preferably, in this embodiment, the wafer processing method further includes a step of polishing the silicon-germanium layer 24 using, e.g., a Chemical Mechanical Polishing (CMP) method to improve the smoothness of the silicon-germanium layer 24.

Particularly, the silicon oxide layer is primarily made of silicon dioxide (SiₓO₂₋ₓ), which is produced by reacting silicon in the denuded zone layer 22 of the silicon wafer with oxygen that is clustered at the crystal interface of the silicon because of the out-diffusion behavior thereof.

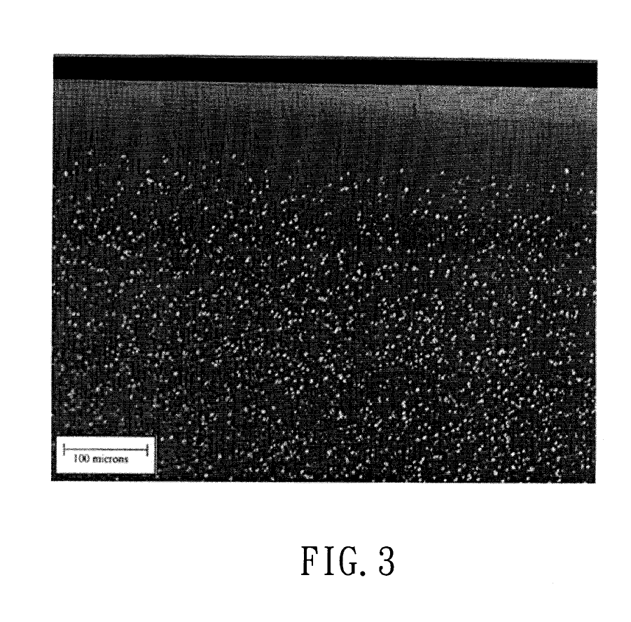

Referring to FIG. 3, the scanning electron microscopic photograph of the surface of the processed silicon wafer A illustrates that the silicon-germanium layer 24 is extremely smooth, so that the wafer processing method of this invention is indeed applicable to produce silicon wafers suitable for conducting a nanometer process.

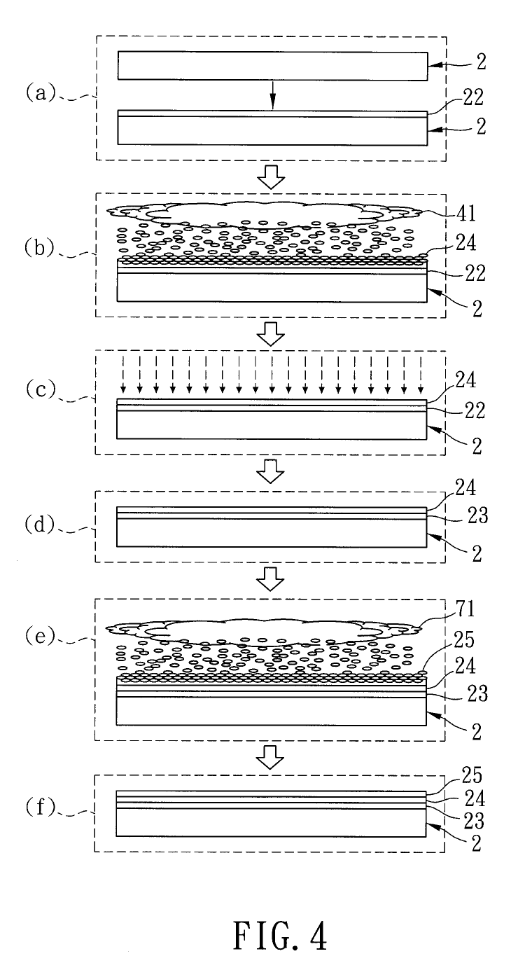

Referring to FIG. 4, the wafer processing method of the second preferred embodiment according to the present invention is similar to that of the first preferred embodiment except for the differences described below. The second preferred embodiment of the wafer processing method further comprises, after step (d), (e) depositing a silicon layer 25 on the silicon-germanium layer 24, and, after step (e), (f) polishing the silicon layer 25. In step (e), the silicon layer 25 is deposited by chemical vapor deposition using a gas source 71 of silicon, and in step (f) the polishing is conducted using a CMP method.

In this embodiment, the annealing in steps (a) and (d) is conducted in a rapid thermal process apparatus under an atmosphere selected from the group consisting of hydrogen, argon, nitrogen and rare gas for 1.0 minute to 60 minutes in step (a) and for 1.0 minute to 4 hours in step (d). Alternatively, it may be conducted in a furnace tube.

Particularly, the polishing in step (f) is applied to improve the smoothness of the silicon layer 25. However, if the smoothness of the silicon layer 25 has already reached the industrial requirement, the polishing step can be omitted.

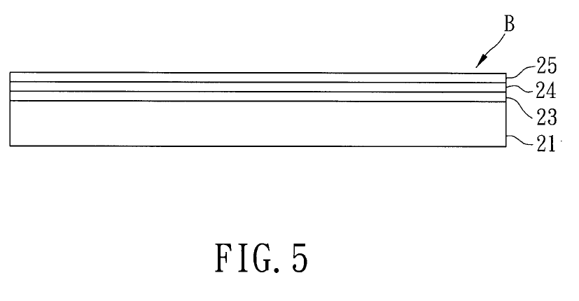

A processed silicon wafer B produced by the wafer processing method of the second preferred embodiment is shown in FIG. 5. The structure of the processed silicon wafer B is similar to that of the processed silicon wafer A which is produced by the first preferred embodiment, except that the processed silicon wafer B further includes a silicon layer 25 on the silicon-germanium layer 24. The silicon layer 25 can be used to prevent the silicon-germanium layer 24 from escaping when the silicon-germanium layer 24 is in a condition where the temperature is higher than 500° C. The thickness of the silicon layer 25 could vary based on actual requirements.

By virtue of the annealing step (a) to form the denuded zone layer 22 and the step of depositing the silicon-germanium layer 24, the low quality test wafer can be processed to become a high quality wafer, thereby enhancing the utilization of the silicon single crystal ingot.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A wafer processing method, comprising the steps of:
(a) annealing a silicon wafer at a temperature higher than 650° C.;
(b) after step (a), depositing a silicon-germanium layer on the silicon wafer;
(c) after step (b), implanting oxygen ions into the silicon wafer; and
(d) after step (c), annealing the silicon wafer at a temperature higher than 650° C. to forma silicon oxide layer underneath the silicon-germanium layer.

2. The wafer processing method of claim 1, wherein, in step (c), the oxygen ions are implanted into the silicon wafer at a concentration ranging from 1×10¹³ to 5×10²¹ atoms/cm³, and a depth ranging from 0.001 μm to 5 μm.

3. The wafer processing method of claim 1, wherein step (a) is conducted in a high temperature furnace tube under an atmosphere selected from the group consisting of hydrogen, argon, nitrogen and rare gas for 10 minutes to 60 minutes.

4. The wafer processing method of claim 1, wherein step (a) is conducted in a rapid thermal process apparatus under an atmosphere selected from the group consisting of hydrogen, argon, nitrogen and rare gas for 1.0 minute to 60 minutes.

5. The wafer processing method of claim 1, wherein step (d) is conducted in a high temperature furnace tube under an atmosphere selected from the group consisting of hydrogen, argon, nitrogen and rare gas for 10 minutes to 4 hours.

6. The wafer processing method of claim 1, wherein step (d) is conducted using a rapid annealing apparatus under an atmosphere selected from the group consisting of hydrogen, argon, nitrogen and rare gas for 1.0 minute to 4 hours.

7. The wafer processing method of claim 1, wherein step (b) is conducted using a chemical vapor deposition method.

8. The wafer processing method of claim 1, further comprising, after step (d), step (e) of depositing a silicon layer on the silicon-germanium layer.

9. The wafer processing method of claim 8, further comprising, after step (e), step (f) of polishing the silicon layer.

10. A silicon wafer obtained from the wafer processing method of claim 1.
